(19) United States
(12) Patent Application Publication
(10) Pub. No.: US 2026/0101441 A1
(43) Pub. Date: Apr. 9, 2026

(54) BOARD AND SERVER

(71) Applicant: SUZHOU METABRAIN INTELLIGENT TECHNOLOGY CO., LTD., Suzhou, Jiangsu (CN)

(72) Inventors: Zhen LIU, Suzhou, Jiangsu (CN); Tanlong CI, Suzhou, Jiangsu (CN); Huijuan JIA, Suzhou, Jiangsu (CN)

(21) Appl. No.: 19/112,781

(22) PCT Filed: Aug. 8, 2024
(86) PCT No.: PCT/CN2024/110676

§ 371 Date: Mar. 18, 2025

(30) Foreign Application Priority Data
Sep. 25, 2023 (CN) 202311244661.4

(51) Int. Cl. H05K 1/181; H05K 1/14; H05K 7/14

(52) U.S. Cl. CPC H05K 1/181; H05K 1/144; H05K 7/1488; H05K 2201/09245; H05K 2201/10212

(57) ABSTRACT

The embodiments of the present disclosure provide a board and a server, which relates to the technical field of processor board card interconnection. By arranging the first internal connectors in the second internal connector configuration area and the second internal connectors in the first internal connector configuration area; the first processor is electrically connected to the first internal connectors through the first circuit, and the second processor is electrically connected to the second internal connectors through the second circuit, and the first circuit and the second circuit are arranged in an intersecting way. Based on the wiring design of the board of the embodiments of the present disclosure for multi-board interconnection, the complexity of the cable topology structure in the board group may be effectively simplified, thereby improving the maintenance efficiency of multi-card interconnection, and reducing the construction difficulty and maintenance cost.

### CROSS-REFERENCE TO RELATED APPLICATION

The present disclosure claims the priority of Chinese patent application filed in CNIPA on Sep. 25, 2023 with the application number of 202311244661.4 and the application name of “A Chip Board and Server”, the entire contents of which are incorporated into the present disclosure by reference.

### FIELD

The present disclosure relates to the technical field of processor board interconnection, in particular to a board and a server.

### BACKGROUND

With the development of artificial intelligence, machine learning, high-performance computing and other complex computing scenarios, higher requirements are put forward for the data center architecture. Computing platforms requirements for different processing tasks are different, and computing power requirements for different application scenarios are different. In order to meet different requirements for data processing, data throughput and resource in different scenarios, the data center accelerates the transformation from a computing-centric architecture to a data-centric converged architecture. In the converged architecture, key devices such as CPU, GPU and SSD are decoupled into independent resource pools, and PCIe (a high-speed signal) bus has become the only carrier connecting many independent resource pools. Between CPU and GPU, between CPU and SSD, and between CPUs in different independent resource pools, huge data interaction is maintained through PCIe bus. In order to support the huge PCIe resource demand, the converged architecture design is introduced into PCIe Switch (also known as high-speed serial expansion bus switch) processors. Usually, multiple PCIe Switch processors are configured in one chassis. However, due to the complex construction of the converged architecture system, there are a large number of components, and the space of the chassis is limited, which makes it difficult and costly to build the converged architecture.

### SUMMARY

In view of the above problems, the embodiments of the present disclosure propose a processor board and a server which may overcome or at least partially solve the above problems.

The embodiments of the present disclosure discloses a processor board, wherein the processor board is configured with a first processor and a second processor;
the first processor is provided with a corresponding first internal connector configuration area, and the first internal connector configuration area is arranged close to one side of the first processor;
the second processor is provided with a corresponding second internal connector configuration area, and the second internal connector configuration area is arranged close to one side of the second processor;
the first processor is configured with a corresponding first internal connector, and the second processor is configured with a corresponding second internal connector; and
the first internal connector is arranged in the second internal connector configuration area, and the second internal connector is arranged in the first internal connector configuration area; the first processor and the first internal connector are electrically connected through a first circuit, and the second processor and the second internal connector are electrically connected through a second circuit.

Optionally, the first processor is provided with a corresponding third internal connector configuration area, and the third internal connector configuration area is arranged at a central area of the processor board close to one side of the first processor;
the second processor is provided with a corresponding fourth internal connector configuration area, and the fourth internal connector configuration area is arranged at one side of the central area close to the second processor;
the first processor is configured with a corresponding third internal connector, and the second processor is configured with a corresponding fourth internal connector;
the third internal connector is arranged in the third internal connector configuration area, and the fourth internal connector is arranged in the fourth internal connector configuration area; the first processor and the third internal connector are electrically connected through a third circuit, the second processor and the fourth internal connector are electrically connected through a fourth circuit, and the third circuit does not intersect with the fourth circuit.

Optionally, the third circuit and the first circuit do not intersect with the second circuit.

Optionally, the fourth circuit and the first circuit do not intersect with the second circuit.

Optionally, the first processor is provided with a corresponding first external connector configuration area, and the first external connector configuration area is arranged at an upper edge position of the processor board close to one side of the first processor.

Optionally, the second processor is provided with a corresponding second external connector configuration area, and the second external connector configuration area is arranged at an upper edge position of the processor board close to one side of the second processor.

Optionally, the first processor is configured with a corresponding first external connector, and the second processor is configured with a corresponding second external connector;
the first external connector are arranged in the first external connector configuration area, and the second external connector is arranged in the second external connector configuration area; the first processor and the first external connector are electrically connected through a fifth circuit, the second processor and the second external connector are electrically connected through a sixth circuit, and the fifth circuit does not intersect with the sixth circuit.

Optionally, the processor board is connected to other processor boards through the first internal connector, the second internal connector, the third internal connector and the fourth internal connector to form a processor board group;
the other processor boards have same structures as the processor board.

Optionally, the processor board group is formed by stacking the other processor boards and the processor board.

Optionally, the processor board group is configured in a two-unit chassis, and a quantity of layers of the processor board group is four.

The embodiments of the present disclosure also discloses a server, wherein the server is configured with a processor board, and the processor board is configured with a first processor and a second processor;
the first processor is provided with a corresponding first internal connector configuration area, and the first internal connector configuration area is arranged close to one side of the first processor;
the second processor is provided with a corresponding second internal connector configuration area, and the second internal connector configuration area is arranged close to one side of the second processor;
the first processor is configured with a corresponding first internal connector, and the second processor is configured with a corresponding second internal connector; and
the first internal connector is arranged in the second internal connector configuration area, and the second internal connector is arranged in the first internal connector configuration area; the first processor and the first internal connector are electrically connected through a first circuit, and the second processor and the second internal connector are electrically connected through a second circuit.

Optionally, the first processor is provided with a corresponding third internal connector configuration area, and the third internal connector configuration area is arranged at a central area of the processor board close to one side of the first processor;
the second processor is provided with a corresponding fourth internal connector configuration area, and the fourth internal connector configuration area is arranged at one side of the central area close to the second processor;
the first processor is configured with a corresponding third internal connector, and the second processor is configured with a corresponding fourth internal connector;
the third internal connector is arranged in the third internal connector configuration area, and the fourth internal connector is arranged in the fourth internal connector configuration area; the first processor and the third internal connector are electrically connected through a third circuit, the second processor and the fourth internal connector are electrically connected through a fourth circuit, and the third circuit does not intersect with the fourth circuit.

Optionally, the third circuit and the first circuit do not intersect with the second circuit.

Optionally, the fourth circuit and the first circuit do not intersect with the second circuit.

Optionally, the first processor is provided with a corresponding first external connector configuration area, and the first external connector configuration area is arranged at an upper edge position of the processor board close to one side of the first processor.

Optionally, the second processor is provided with a corresponding second external connector configuration area, and the second external connector configuration area is arranged at an upper edge position of the processor board close to one side of the second processor.

Optionally, the first processor is configured with a corresponding first external connector, and the second processor is configured with a corresponding second external connector;
the first external connector are arranged in the first external connector configuration area, and the second external connector is arranged in the second external connector configuration area; the first processor and the first external connector are electrically connected through a fifth circuit, the second processor and the second external connector are electrically connected through a sixth circuit, and the fifth circuit does not intersect with the sixth circuit.

Optionally, the processor board is connected to other processor boards through the first internal connector, the second internal connector, the third internal connector and the fourth internal connector to form a processor board group;
the other processor boards have same structures as the processor board.

Optionally, the processor board group is formed by stacking the other processor boards and the processor board.

Optionally, the processor board group is configured in a two-unit chassis, and a quantity of layers of the processor board group is four.

The embodiments of the present disclosure include the following advantage.

In the embodiments of the present disclosure, a expansion bus processor board is configured with a first expansion bus processor and a second expansion bus processor; The first expansion bus processor is provided with a corresponding first internal connector configuration area, which is arranged at a lower edge position of the expansion bus processor board close to the first expansion bus processor side; The second expansion bus processor is provided with a corresponding second internal connector configuration area, which is arranged at a lower edge position close to the second expansion bus processor; The first expansion bus processor is configured with a corresponding first internal connector, and the second expansion bus processor is configured with a corresponding second internal connector; The first internal connector is arranged in the second internal connector configuration area, and the second internal connector is arranged in the first internal connector configuration area; The first expansion bus processor is electrically connected to the first internal connector through a first circuit, the second expansion bus processor is electrically connected to the second internal connector through a second circuit, and the first circuit and the second circuit are arranged in an intersecting way. Multi-board interconnection based on the wiring design of the processor board in the embodiments of the present disclosure may effectively simplify the complexity of the cable topology structure in the processor board group, thereby improving the maintenance efficiency of multi-board interconnection and reducing the construction difficulty and maintenance cost.

### BRIEF DESCRIPTION OF THE DRAWINGS

FIG. 1 is a schematic structural diagram of an expansion bus processor board in a related art;

FIG. 2 is a schematic structural diagram A of a processor board provided in an embodiment of the present disclosure;

FIG. 3 is a schematic diagram of topological cable interconnection of a layout in a related art;

FIG. 4 is a schematic structural diagram A of a cable interconnection topology provided by an embodiment of the present disclosure;

FIG. 5 is a schematic structural diagram B of a processor board provided in an embodiment of the present disclosure;

FIG. 6 is a schematic structural diagram of a cable interconnection topology provided by the related art;

FIG. 7 is a schematic structural diagram A of a processor board group provided in an embodiment of the present disclosure;

FIG. 8 is a schematic structural diagram C of a cable interconnection topology provided by an embodiment of the present disclosure;

FIG. 9 is a schematic structural diagram B of a processor board group provided in an embodiment of the present disclosure;

FIG. 10 is a schematic structural diagram D of a cable interconnection topology provided by an embodiment of the present disclosure;

FIG. 11 is a schematic structural diagram C of a processor board group provided in an embodiment of the present disclosure.

Reference numerals: expansion bus processor board 10, first expansion bus processor 101, second expansion bus processor 102, first internal connector configuration area 101a, second internal connector configuration area 102a, first internal connector 1011, second internal connector 1021, first circuit 103, second circuit 104, third internal connector configuration area 101b, fourth internal connector configuration area 102b, third internal connector 1012, fourth internal connector 1022, third circuit 105, fourth circuit 106, first external connector configuration area 101c, second external connector configuration area 102c, first external connector 1013, second external connector 1023, fifth circuit 107, sixth circuit 108, other expansion bus processor boards 20, and expansion bus processor board group 30.

### DETAILED DESCRIPTION

In the following, the technical solution in the embodiments of the present disclosure will be clearly and completely described with reference to the appended drawings in the embodiments of the present disclosure. Apparently, the described embodiments are a part of the embodiments of the present disclosure, but not the whole embodiment. Based on the embodiments in the present disclosure, all other embodiments obtained by persons skilled in the art without expenditure of creative labor belong to the protection scope of the present disclosure.

In order to make the above objects, features and advantages of the present disclosure more obvious and easy to understand, the present disclosure will be further described in detail with the appended drawings and specific embodiments.

In order to make persons skilled in the art better understand the embodiments of the present disclosure, some technical terms involved in the embodiments of the present disclosure are explained below.

CPU: Central Processing Unit (CPU for short) is the operation and control core of computer system, and it is the final execution unit of information processing and program running. Since the emergence of CPU, it has made great progress in logical structure, operating efficiency and functional extension.

GPU: Graphics Processing Unit (GPU for short), also known as a display core, a visual processor, or a display processor, is a microprocessor specifically designed to perform image and graphics-related computations on personal computers, workstations, game consoles, and some mobile devices such as tablets and smartphones. The GPU reduces the reliance of the graphics board on the CPU and takes over some of the CPU's tasks. Especially in 3D graphics processing, the core technologies adopted by the GPU include hardware T&L (geometric transformation and illumination processing), cubic environment material mapping, vertex blending, texture compression, bump mapping, dual-texture four-pixel 256-bit rendering engine, etc. Among them, the hardware T&L technology may be regarded as a hallmark of the GPU.

SSD (Solid State Disk, also known as solid state hard disk) is a hard disk made of solid-state electronic storage processor array, and it is a computer storage device mainly using flash memory as permanent memory. It consists of a control unit and a storage unit. It is widely used in industrial control, video monitoring, network monitoring, network terminals, navigation equipment and many other fields.

PCIe (Peripheral Component Interconnect Express) is an expension bus standard for high-speed serial computers. Its original name is “3GIO”, which aims to replace the old PCI, PCI-X and AGP bus standards. PCIe is a high-speed serial point-to-point dual-channel high-bandwidth transmission. The connected devices are allocated exclusive channel bandwidth, and do not share bus bandwidth. It mainly supports active power management, error reporting, end-to-end reliable transmission, hot plug and quality of service (QOS) and other functions.

PCIe Switch (also called high-speed serial expansion bus switch) provides expansion or aggregation capability, and allows more devices to connect to a PCle port. They act as packet routers and identify which path a given packet needs to take according to address or other routing information.

I/O Box (Input/Output Box), I/O Box refers to a device that provides an input/output (I/O) interface for connecting various network components. I/O Box may also be used as a network switch, allowing multiple devices to connect to a common network resource.

CXL, (Computer Express Link) is a high-speed interconnection protocol, which aims to provide higher data throughput and lower latency to meet the needs of modern computing and storage systems.

CXL Switch: A SW processor based on CXL protocol.

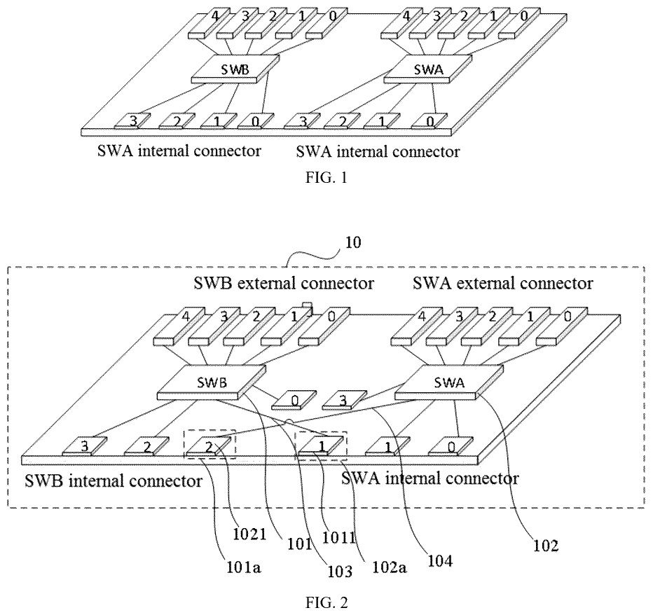

In practical application, in order to meet different data processing, data throughput and resource requirements in different scenarios, the data center is accelerating the transformation from a computing-centric architecture to a data-centric converged architecture. In the traditional server architecture design, PCIe Switch processor and CPU belong to a single master-slave relationship, which is used to expand PCIe resources of a single CPU. However, under the converged architecture, all PCIe resources in a cabinet are concentrated in one I/O Box. In order to share PCIe resources, several PCIe Switch processors are networked in the I/O Box. However, because the whole cabinet system has a certain body space, the body space of the I/O Box is limited (Illustratively, a height of 2 Units, where 1 Unit=4.445 cm). In order to realize the complex topology interconnection of PCIe Switch in a limited space and mount as many end devices as possible, one or two PCIe Switch processors are usually mounted under a CPU (refer to FIG. 1, FIG. 1 shows a structural schematic diagram of an expansion bus processor board in the related art), to expand PCIe resources, or to integrate multiple PCIe Switch processors on a board and realize interconnection among multiple PCIe Switch processors through intra-board wiring or cable interconnection. However, the above-mentioned methods cannot adapt to the application scenarios of resource pooling systems and cannot build a complex system topology. It is impossible to support the implementation of the converged architecture system, and the wiring is difficult, and the processing and maintenance costs are high. It is extremely difficult to debug, and it is also impossible to flexibly adjust the interconnection topology, and it is impossible to achieve downward compatibility for other topologies. The embodiments of the present disclosure propose a processor board, which combines the first internal connector configuration area and the second internal connector configuration area to optimize the layout of the processor board, and at the same time enables the processor board to downward compatibility for other interconnection topologies, further reducing the processing and maintenance costs.

In specific implementation, the processor board of the embodiments of the present disclosure may include, but is not limited to, an expansion bus processor board supporting PCIe protocol and a processor board supporting CXL protocol. Similarly, the first processor and the second processor may be a PCIe Switch or a CXL Switch.

In order to make those skilled in the art better understand the embodiments of the present disclosure, the embodiments of the present disclosure will be explained below by taking an expansion bus processor board as an example.

Referring to FIG. 2, a schematic structural diagram A of a processor board provided in an embodiment of the present disclosure is shown. The expansion bus processor board 10 is configured with a first expansion bus processor 101 and a second expansion bus processor 102.

The first expansion bus processor 101 is provided with a corresponding first internal connector configuration area 101a, and the first internal connector configuration area 101a is arranged at the lower edge position of the expansion bus processor board 10 close to one side of the first expansion bus processor 101;

The second expansion bus processor 102 is provided with a corresponding second internal connector configuration area 102a, and the second internal connector configuration area 102a is arranged at the lower edge position close to one side of the second expansion bus processor 102;

The first expansion bus processor 101 is configured with a corresponding first internal connector 1011, and the second expansion bus processor 102 is configured with a corresponding second internal connector 1021.

The first internal connector 1011 is arranged in the second internal connector configuration area 102a, and the second internal connector 1021 is arranged in the first internal connector configuration area 101a; The first expansion bus processor 101 and the first internal connector 1011 are electrically connected through a first circuit 103, and the second expansion bus processor 102 and the second internal connector 1021 are electrically connected through a second circuit 104, and the first circuit 103 and the second circuit 104 are arranged in an intersecting way.

In some embodiments of the present disclosure, the processor board may be a chip board, a first expansion bus processor 101 (that is, the first processor), and/or a second expansion bus processor 102 (that is, the second processor), which may be a chip.

In practical application, the expansion bus processor board 10 in the embodiments of the present disclosure may be a printed circuit board assembly (PCBA) board equipped with an expansion bus processor, and the PCBA refers to a printed circuit board that has undergone component mounting. The PCB is an important electronic component, a supporting body of electronic components, and is the provider of circuit connection of electronic components. The PCB is called “printed circuit board”, because it is made by electronic printing technology. Before the appearance of printed circuit board, the interconnection between electronic components depended on the direct connection of wires to form a complete circuit. In addition, the first expansion bus processor 101 and/or the second expansion bus processor 102 may be PCIe Switch processors, also known as high-speed serial expansion bus switch processors, and at the same time, the first internal connector and/or the second internal connector may be an internal MCIO connector (Mini Cool Edge IO connector, also known as a cable assembly connector, may provide additional flexibility for signal use in high-performance channel systems).

In specific implementation, the expansion bus processor board 10 may be configured with a first expansion bus processor 101 and a second expansion bus processor 102, the first expansion bus processor 10 is provided with a corresponding first internal connector configuration area 101a, which is arranged at the lower edge position of the expansion bus processor board 10 close to one side of the first expansion bus processor 101; The second expansion bus processor 102 is provided with a corresponding second internal connector configuration area 102a, and the second internal connector configuration area 102a is arranged at the lower edge position close to one side of the second expansion bus processor 102; The first expansion bus processor 101 is configured with a corresponding first internal connector 1011, and the second expansion bus processor 102 is configured with a corresponding second internal connector 1021. The first internal connector 1011 is arranged in the second internal connector configuration area 102a, and the second internal connector 1021 is arranged in the first internal connector configuration area 101a; The first expansion bus processor 101 and the first internal connector 1011 are electrically connected through a first circuit 103, and the second expansion bus processor 102 and the second internal connector 1021 are electrically connected through a second circuit 104, and the first circuit 103 and the second circuit 104 are arranged in an intersecting way. Illustratively, the topological cable interconnection of the expansion bus processor board is shown in Table 1.

TABLE 1

| | SW0 | SW2 | SW4 | SW6 |
|---|---|---|---|---|
| | internal | internal | internal | internal |
| | connector | connector | connector | connector |
| SW1 | 0-3 ←→ | 2-2 ←→ | 4-1 ←→ | 6-0 ←→ |
| internal | 1-0 | 1-3 | 1-1 | 1-2 |
| connector | | | | |
| SW3 | 0-0 ←→ | 2-3 ←→ | 4-2 ←→ | 6-1 ←→ |
| internal | 3-1 | 3-0 | 3-3 | 3-2 |
| connector | | | | |
| SW5 | 0-2 ←→ | 2-0 ←→ | 4-3 ←→ | 6-2 ←→ |
| internal | 5-2 | 5-1 | 5-0 | 5-3 |
| connector | | | | |
| SW7 | 0-1 ←→ | 2-1 ←→ | 4-0 ←→ | 6-3 ←→ |
| internal | 7-3 | 7-2 | 7-1 | 7-0 |
| connector | | | | |

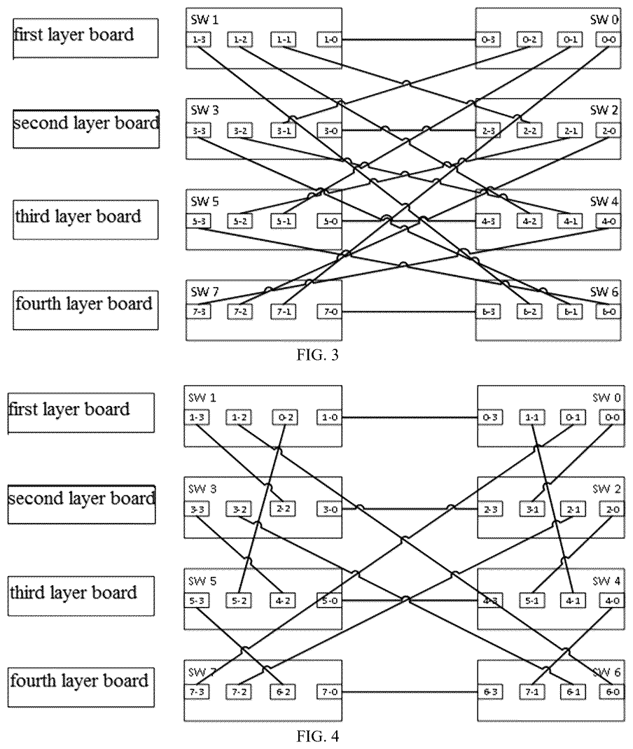

Let the first expansion bus processors be designated as “SW1”, “SW3”, “SW5” and “SW7”, the second expansion bus processors as “SW0”, “SW2”, “SW4” and “SW6”, the first internal connectors as “1-1”, “3-1”, “5-1”, “7-1” corresponding to the first expansion bus processors “SW1”, “SW3”, “SW5” and “SW7” respectively, and the second internal connectors as “0-2”, “2-2”, “4-2”, “6-2” corresponding to the second expansion bus processors “SW0”, “SW2”, “SW4” and “SW6” respectively. If an interconnection method of the related art in FIG. 1 is followed, a connection result is as shown in FIG. 3, which makes the multi-board cable interconnection topology extremely complex, resulting in high cost of construction and maintenance, and low maintenance efficiency. However, the interconnection relationship of the embodiment of the present disclosure is shown in FIG. 4. It can be seen that the embodiment of the present disclosure greatly simplifies the complexity of cables under the condition of the same cable interconnection topology.

In the embodiments of the present disclosure, the expansion bus processor board is configured with the first expansion bus processor and the second expansion bus processor; The first expansion bus processor is provided with the corresponding first internal connector configuration area, which is arranged at a lower edge position of the expansion bus processor board close to the first expansion bus processor side; The second expansion bus processor is provided with the corresponding second internal connector configuration area, which is arranged at a lower edge position close to the second expansion bus processor; The first expansion bus processor is configured with the corresponding first internal connector, and the second expansion bus processor is configured with the corresponding second internal connector; The first internal connector is arranged in the second internal connector configuration area, and the second internal connector is arranged in the first internal connector configuration area; The first expansion bus processor is electrically connected to the first internal connector through a first circuit, the second expansion bus processor is electrically connected to the second internal connector through a second circuit, and the first circuit and the second circuit are arranged in an intersecting way, so that the complexity of the board cable is reduced, and the board cost is further reduced.

On the basis of the above-mentioned embodiments, a modified embodiment of the above-mentioned embodiments is proposed. It should be noted here that in order to make the description brief, only the differences from the above-mentioned embodiments are described in the modified embodiment.

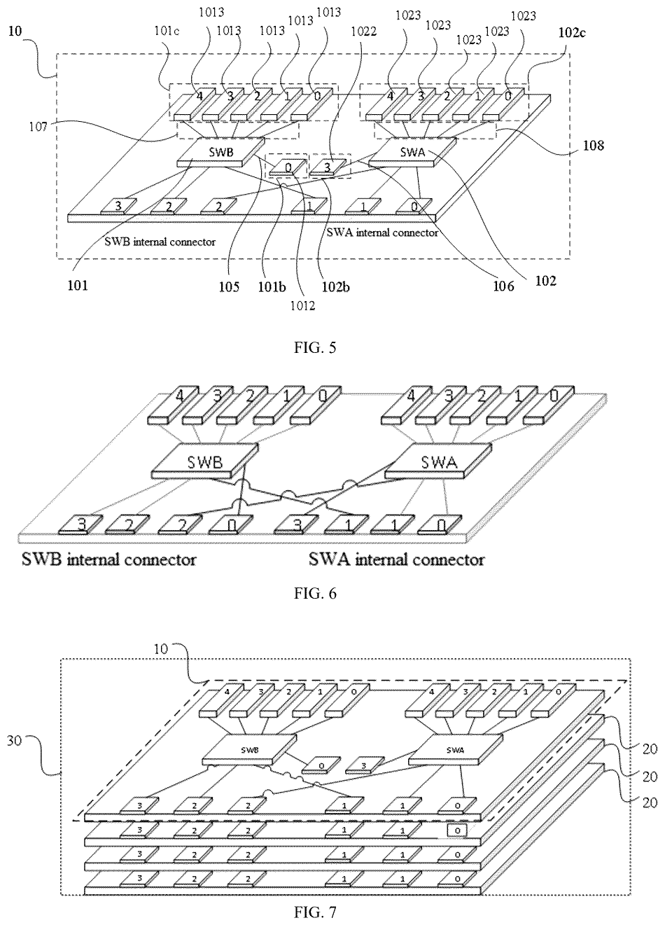

Referring to FIG. 5, a structural schematic diagram B of a processor board provided in an embodiment of the present disclosure is shown.

In an alternative embodiment of the present disclosure, the first expansion bus processor 101 is provided with a corresponding third internal connector configuration area 101b, which is arranged in a central area of the expansion bus processor board 10 close to one side of the first expansion bus processor 101;

The second expansion bus processor 102 is provided with a corresponding fourth internal connector configuration area 102b, and the fourth internal connector configuration area 102b is arranged in a central area close to one side of the second expansion bus processor 102;

The first expansion bus processor 101 is configured with a corresponding third internal connector 1012, and the second expansion bus processor 102 is configured with a corresponding fourth internal connector 1022.

The third internal connector 1012 is arranged in the third internal connector arrangement area 101b, and the fourth internal connector 1022 is arranged in the fourth internal connector arrangement area 102b; The first expansion bus processor 101 and the third internal connector 1012 are electrically connected through a third circuit 105, while the second expansion bus processor 102 and the fourth internal connector 1022 are electrically connected through a fourth circuit 106, and the third circuit 105 does not intersect with the fourth circuit 106.

In practical application, the third internal connector, and/or the fourth internal connector in the embodiments of the present disclosure may be an internal MCIO connector.

In the specific implementation, the first expansion bus processor in the embodiment of the present disclosure is provided with a corresponding third internal connector configuration area, and the third internal connector configuration area is arranged in the central area of the expansion bus processor board close to one side of the first expansion bus processor; The second expansion bus processor is provided with a corresponding fourth internal connector configuration area, and the fourth internal connector configuration area is arranged in the central area close to one side of the second expansion bus processor; The first expansion bus processor is configured with a corresponding third internal connector, and the second expansion bus processor is configured with a corresponding fourth internal connector; The third internal connector is arranged in the third internal connector configuration area and the fourth internal connector is arranged in the fourth internal connector configuration area; The first expansion bus processor is electrically connected to the third internal connector through a third circuit, the second expansion bus processor is electrically connected to the fourth internal connector through a fourth circuit, and the third circuit does not intersect with the fourth circuit. Illustratively, when the first expansion bus processor is “SWB”, the second expansion bus processor is “SWA”, the third internal connector is “0” and the fourth internal connector is “3”, then “0” and “3” may be respectively placed in the third internal connector configuration area 101b and the fourth internal connector configuration area 102b in FIG. 5, and “SWB” and “0” are electrically connected through the third circuit 105, and “SWA” and “3” are electrically connected through the fourth circuit 106, wherein the third circuit 105 does not intersect with the fourth circuit 106. Referring to FIG. 6, FIG. 6 is a schematic structural diagram of a cable interconnection topology provided by the related art. FIG. 6 shows a result of circuit connection according to the related art under the same conditions. It can be seen that the embodiment of the present disclosure greatly simplifies the complexity of cables under the condition of the same topological cable interconnection, and at the same time, the length of the third circuit 105 and the fourth circuit 106 is shortened, thus improving the signal quality.

In the embodiments of the present disclosure, the first expansion bus processor is provided with a corresponding third internal connector configuration area, and the third internal connector configuration area is arranged in the central area of the expansion bus processor board close to one side of the first expansion bus processor; The second expansion bus processor is provided with a corresponding fourth internal connector configuration area, and the fourth internal connector configuration area is arranged in the central area close to one side of the second expansion bus processor; The first expansion bus processor is configured with a corresponding third internal connector, and the second expansion bus processor is configured with a corresponding fourth internal connector; The third internal connector is arranged in the third internal connector configuration area and the fourth internal connector is arranged in the fourth internal connector configuration area; The first expansion bus processor is electrically connected to the third internal connector through a third circuit, the second expansion bus processor is electrically connected to the fourth internal connector through a fourth circuit, and the third circuit does not intersect with the fourth circuit, thus reducing the manufacturing cost of the board and further improving the signal quality.

An embodiment of the present disclosure, the third circuit 105 and the first circuit 103 do not intersect with the second circuit 104.

In the specific implementation, the multi-layer crossing of PCIe high-speed signals will increase the board layers, which will lead to an increase of PCBA cost. Therefore, by reducing the complexity of cables and reducing intersection points of the cables, the increase of PCBA cost caused by the multi-layer crossing of PCIe high-speed signals may be effectively avoided.

According to the embodiments of the present disclosure, the third circuit and the first circuit do not intersect with the second circuit, so that the processing cost of the board is reduced.

An embodiment of the present disclosure, the fourth circuit 106 and the first circuit 103 do not intersect with the second circuit 104.

In the specific implementation, the multi-layer crossing of PCIe high-speed signals will increase the board layers, which will lead to an increase of PCBA cost. Therefore, by reducing the complexity of cables and reducing intersection points of the cables, the increase of PCBA cost caused by the multi-layer crossing of PCIe high-speed signals may be effectively avoided.

According to the embodiments of the present disclosure, the fourth circuit and the first circuit are not intersected with the second circuit, so that the processing cost of the board is further reduced.

In an alternative embodiment of the present disclosure, the first expansion bus processor 101 is provided with a corresponding first external connector configuration area 101c, which is arranged at an upper edge position of the expansion bus processor board 10 close to one side of the first expansion bus processor 101.

In practical application, by arranging the external connector configuration area in a position close to the corresponding expansion bus processor, the intersection points and the length of cables may be effectively reduced, so that the signal quality may be guaranteed and the processing cost of the board may be reduced.

According to the embodiments of the present disclosure, the first expansion bus processor is provided with the corresponding first external connector configuration area, and the first external connector configuration area is arranged at the upper edge position of the expansion bus processor board close to one side of the first expansion bus processor, thereby further ensuring the signal quality and reducing the processing cost of the board.

An embodiment of the present disclosure, the second expansion bus processor 102 is provided with a corresponding second external connector configuration area 102c, and the second external connector configuration area 102c is arranged at the upper edge position of the expansion bus processor board 10 close to one side of the second expansion bus processor 102.

In practical application, by arranging the external connector configuration area in a position close to the corresponding expansion bus processor, the intersection points and the length of cables may be effectively reduced, so that the signal quality may be guaranteed and the processing cost of the board may be reduced.

According to the embodiments of the present disclosure, the second expansion bus processor is provided with the corresponding second external connector configuration area, and the second external connector configuration area is arranged at the upper edge position of the expansion bus processor board close to one side of the second expansion bus processor, so that the signal quality is further guaranteed and the processing cost of the board is reduced.

In an alternative embodiment of the present disclosure, the first expansion bus processor 101 is configured with a corresponding first external connector 1013, and the second expansion bus processor 102 is configured with a corresponding second external connector 1023;

The first external connector 1013 is arranged in the first external connector arrangement area 101c, and the second external connector 1023 is arranged in the second external connector arrangement area 102a. The first expansion bus processor 101 and the first external connector 1013 are electrically connected through a fifth circuit 107, while the second expansion bus processor 102 and the second external connector 1023 are electrically connected through a sixth circuit 108, and the fifth circuit 107 and the sixth circuit 108 do not intersect.

Illustratively, the first external connector and/or the second external connector may be an external CDFP (400 Form factor Pluggable) connector, which is a high-speed signal connector and may be used for signal transmission between different I/O boxes.

In the embodiments of the present disclosure, the first expansion bus processor is configured with a corresponding first external connector, and the second expansion bus processor is configured with a corresponding second external connector; The first external connector is arranged in the first external connector configuration area, and the second external connector is arranged in the second external connector configuration area; The first expansion bus processor and the first external connector are electrically connected through a fifth circuit, the second expansion bus processor and the second external connector are electrically connected through a sixth circuit, and the fifth circuit and the sixth circuit do not intersect, so that a plurality of I/O boxes may transmit signals mutually, the signal transmission quality is guaranteed, and the manufacturing cost of the board is further reduced.

Referring to FIG. 7, FIG. 7 shows a schematic structural diagram A of a processor board group provided in an embodiment of the present disclosure;

In an optional embodiment of the present disclosure, the expansion bus processor board 10 is connected to other expansion bus processor boards 20 through a first internal connector 1011, a second internal connector 1021, a third internal connector 1012 and a fourth internal connector 1022 to form an expansion bus processor board group 30.

Other expansion bus processor boards 20 have the same structure as the expansion bus processor board 10.

In practical application, when a topological structure is 2*n, that is, a number of the expansion bus processor boards is n, each of the expansion bus processor boards is provided with two expansion bus processors, if the expansion bus processors are formed into an expansion bus processor group, the space occupied by the chassis may be reduced and a large number of interconnection requirements may be met, and the complexity of PCBA may be simplified, the length of cables may be further reduced and the signal quality may be improved. Illustratively, connections may be made according to the topological cable interconnection relationship shown in Table 1.

In the embodiments of the present disclosure, the expansion bus processor board is connected to other expansion bus processor boards through the first internal connector, the second internal connector, the third internal connector and the fourth internal connector to form an expansion bus processor board group; Other expansion bus processor boards have the same structure as the expansion bus processor boards, thus reducing the space occupation of the chassis, further improving the signal quality and reducing the processing cost of the boards.

An embodiment of the present disclosure, the expansion bus processor board group 30 is formed by stacking the other expansion bus processor boards 20 and the expansion bus processor boards 10.

In the specific implementation, the other expansion bus processor boards 20 and the expansion bus processor boards 10 may be evenly and vertically distributed in the chassis and stacked to form an expansion bus processor board group.

In practical application, the stacked arrangement allows for the replacement of only the damaged board at the specific layer when a board fails, thereby enhancing the system's reliability and maintainability.

According to the embodiments of the present disclosure, the expansion bus processor board group is formed by stacking other expansion bus processor boards and expansion bus processor boards, so that the reliability of the system is improved, the subsequent operation and maintenance work is facilitated, and the operation and maintenance cost is reduced.

An embodiment of the present disclosure, the expansion bus processor board group 30 is configured in a two-unit chassis, and a quantity of layers of the expansion bus processor board group 30 is four.

In practical application, the two-unit chassis in the embodiments of the present disclosure may be a 2 U chassis, and the height of the 2 U chassis is 8.89 cm. The 2 U chassis is usually used for high-performance computer equipment such as servers, and has good heat dissipation and expansibility, and may be installed with multiple hard disks and slots. Illustratively, when the two-unit chassis is a 2 U chassis, the number of layers of the expansion bus processor board group may be four. At the same time, 40 external connectors may be provided to meet the interconnection requirements of a large number of Host/Device, so that the expansion bus processor board group may better adapt to the size of the chassis and make higher use of the chassis space.

According to the embodiment of the present disclosure, the expansion bus processor board group is configured in the two-unit chassis, and the quantity of layers of the expansion bus processor board group is four, so that the space utilization rate of the system chassis is improved.

Optionally, the interconnection mode of the embodiment of the present disclosure may also be compatible with other topologies. Illustratively, the downwards compatibility of 2*3 standard topology and 2*2 Mesh (wireless mesh network) topology may take 2*3 standard topology as an example, that is, three expansion bus processor boards, each of which is provided with two expansion bus processors. Refer to Table 2 for the definition of cable interconnection relationship of standard topology.

TABLE 2

| | SW0 | SW2 | SW4 |
|---|---|---|---|
| | internal | internal | internal |
| | connector | connector | connector |
| SW1 | 0-3 ←→ 1-0 | 2-2 ←→ 1-3 | 4-1 ←→ 1-1 |
| internal | | | |
| connector | | | |
| SW3 | 0-0 ←→ 3-1 | 2-3 ←→ 3-0 | 4-2 ←→ 3-3 |
| internal | | | |
| connector | | | |
| SW5 | 0-2 ←→ 5-2 | 2-0 ←→ 5-1 | 4-3 ←→ 5-0 |
| internal | | | |
| connector | | | |

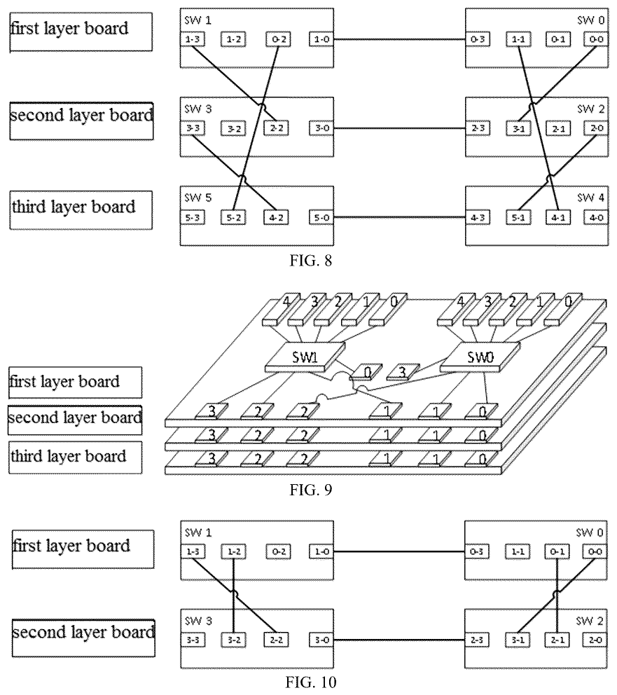

Referring to FIG. 8, FIG. 8 is a schematic diagram C of a cable interconnection topology provided by an embodiment of the present disclosure. FIG. 8 shows a cable topology corresponding to a 2*3 expansion bus processor board group, FIG. 9 is a schematic diagram B of a processor board group provided by an embodiment of the present disclosure, and FIG. 9 shows a stacking structure of an expansion bus processor board group with a 2*3 standard topology. It can be seen that for the cable interconnection mode of 2*3 standard topology, this 2*3 standard topology is a deformation of 2*4 topology, which is compatible in terms of structure and cable layout, and at the same time, there are 30 external connectors that may be used to meet the interconnection needs of a large number of Host/Device.

Take a 2*2 Mesh topology as an example. Refer to Table 3 for the definition of cable interconnection relationship in the 2*2 Mesh topology:

TABLE 3

| | SW0 | SW1 | SW2 | SW3 |
|---|---|---|---|---|
| | internal | internal | internal | internal |
| | connector | connector | connector | connector |
| SW0 | / | | | |
| internal | | | | |
| connector | | | | |
| SW1 | 0-3←→1-0 | / | | |
| internal | | | | |
| connector | | | | |
| SW2 | 0-1←→2-1 | 1.3←→2-2 | / | |
| internal | | | | |
| connector | | | | |
| SW3 | 0-0←→3-1 | 1-2←→3-2 | 2-3←→3-0 | / |
| internal | | | | |
| connector | | | | |

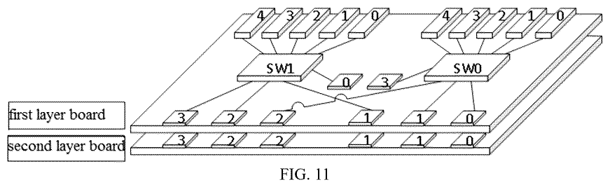

Referring to FIG. 10, FIG. 10 is a schematic diagram D of a cable interconnection topology provided by an embodiment of the present disclosure, and FIG. 10 shows a cable topology of a 2*2 Mesh expansion bus processor board group. Referring to FIG. 11, FIG. 11 is a schematic diagram C of a processor board group provided by an embodiment of the present disclosure, and FIG. 11 shows a stacking structure of an expansion bus processor board group corresponding to a 2*2 Mesh standard topology. It can be seen that the embodiment of the present disclosure may construct a cable interconnection mode for a 2*2 Mesh topology, which is a deformation of a 2*4 topology and has compatibility in terms of structure, cables and the like. At the same time, there are 20 external connectors that may be used to meet the interconnection needs of a large number of Host/Device.

The embodiments of the present disclosure also discloses a server, wherein the server is configured with a processor board, and the processor board is configured with a first processor and a second processor;
the first processor is provided with a corresponding first internal connector configuration area, and the first internal connector configuration area is arranged close to one side of the first processor;
the second processor is provided with a corresponding second internal connector configuration area, and the second internal connector configuration area is arranged close to one side of the second processor;
the first processor is configured with a corresponding first internal connector, and the second processor is configured with a corresponding second internal connector; and
the first internal connector is arranged in the second internal connector configuration area, and the second internal connector is arranged in the first internal connector configuration area; the first processor and the first internal connector are electrically connected through a first circuit, and the second processor and the second internal connector are electrically connected through a second circuit.

Optionally, the first processor is provided with a corresponding third internal connector configuration area, and the third internal connector configuration area is arranged at a central area of the processor board close to one side of the first processor;
the second processor is provided with a corresponding fourth internal connector configuration area, and the fourth internal connector configuration area is arranged at one side of the central area close to the second processor;
the first processor is configured with a corresponding third internal connector, and the second processor is configured with a corresponding fourth internal connector;
the third internal connector is arranged in the third internal connector configuration area, and the fourth internal connector is arranged in the fourth internal connector configuration area; the first processor and the third internal connector are electrically connected through a third circuit, the second processor and the fourth internal connector are electrically connected through a fourth circuit, and the third circuit does not intersect with the fourth circuit.

Optionally, the third circuit and the first circuit do not intersect with the second circuit.

Optionally, the fourth circuit and the first circuit do not intersect with the second circuit.

Optionally, the first processor is provided with a corresponding first external connector configuration area, and the first external connector configuration area is arranged at an upper edge position of the processor board close to one side of the first processor.

Optionally, the second processor is provided with a corresponding second external connector configuration area, and the second external connector configuration area is arranged at an upper edge position of the processor board close to one side of the second processor.

Optionally, the first processor is configured with a corresponding first external connector, and the second processor is configured with a corresponding second external connector;
the first external connector are arranged in the first external connector configuration area, and the second external connector is arranged in the second external connector configuration area; the first processor and the first external connector are electrically connected through a fifth circuit, the second processor and the second external connector are electrically connected through a sixth circuit, and the fifth circuit does not intersect with the sixth circuit.

Optionally, the processor board is connected to other processor boards through the first internal connector, the second internal connector, the third internal connector and the fourth internal connector to form a processor board group;
the other processor boards have same structures as the processor board.

Optionally, the processor board group is formed by stacking the other processor boards and the processor board.

Optionally, the processor board group is configured in a two-unit chassis, and a quantity of layers of the processor board group is four.

As for the server embodiments, because they are basically similar to the embodiments of the expansion bus processor board, the description is relatively simple, and the relevant points may be found in the partial description of the embodiment of the expansion bus processor board.

Although the preferred embodiments of the embodiments of the present disclosure have been described, those skilled in the art may make additional changes and modifications to these embodiments once they know the basic inventive concepts. Therefore, the appended claims are intended to be interpreted as including the preferred embodiment and all changes and modifications that fall within the scope of the embodiments of the present disclosure.

Finally, it should be noted that in this paper, the terms “including”, “containing” or any other variation thereof are intended to cover non-exclusive inclusion, so that a process, method, article or terminal equipment including a series of elements includes not only those elements, but also other elements not explicitly listed, or elements inherent to such process, method, article or terminal equipment. Without more restrictions, the element defined by the sentence “including one . . . ” does not exclude that there are other identical elements in the process, method, article or terminal equipment including the element.

The above is only the specific implementation of the present disclosure, but the protection scope of the present disclosure is not limited to this. Any person skilled in the art can easily think of changes or substitutions within the technical scope disclosed in the present disclosure, which should be covered by the present disclosure. Therefore, the protection scope of the present disclosure should be based on the protection scope of the claims.

1. A board, wherein the board is configured with a first processor and a second processor;
the first processor is provided with a corresponding first internal connector configuration area, and the first internal connector configuration area is arranged close to one side of the first processor;
the second processor is provided with a corresponding second internal connector configuration area, and the second internal connector configuration area is arranged close to one side of the second processor;
the first processor is configured with a corresponding first internal connector, and the second processor is configured with a corresponding second internal connector; and
the first internal connector is arranged in the second internal connector configuration area, and the second internal connector is arranged in the first internal connector configuration area; the first processor and the first internal connector are electrically connected through a first circuit, and the second processor and the second internal connector are electrically connected through a second circuit.

2. The board according to claim 1, wherein the first processor is provided with a corresponding third internal connector configuration area, and the third internal connector configuration area is arranged at a central area of the board close to one side of the first processor;
the second processor is provided with a corresponding fourth internal connector configuration area, and the fourth internal connector configuration area is arranged at the central area close to one side of the second processor;
the first processor is configured with a corresponding third internal connector, and the second processor is configured with a corresponding fourth internal connector; and
the third internal connector is arranged in the third internal connector configuration area, and the fourth internal connector is arranged in the fourth internal connector configuration area; the first processor and the third internal connector are electrically connected through a third circuit, the second processor and the fourth internal connector are electrically connected through a fourth circuit, and the third circuit does not intersect with the fourth circuit.

3. The board according to claim 2, wherein the third circuit and the first circuit do not intersect with the second circuit.

4. The board according to claim 2, wherein the fourth circuit and the first circuit do not intersect with the second circuit.

5. The board according to claim 1, wherein the first processor is provided with a corresponding first external connector configuration area, and the first external connector configuration area is arranged at an upper edge position of the board close to one side of the first processor.

6. The board according to claim 2, wherein the second processor is provided with a corresponding second external connector configuration area, and the second external connector configuration area is arranged at an upper edge position of the board close to one side of the second processor.

7. The board according to claim 6, wherein the first processor is configured with a corresponding first external connector, and the second processor is configured with a corresponding second external connector; and
the first external connector are arranged in the first external connector configuration area, and the second external connector is arranged in the second external connector configuration area; the first processor and the first external connector are electrically connected through a fifth circuit, the second processor and the second external connector are electrically connected through a sixth circuit, and the fifth circuit does not intersect with the sixth circuit.

8. The board according to claim 2, wherein the board is connected to other boards through the first internal connector, the second internal connector, the third internal connector and the fourth internal connector to form a board group; and
the other boards have same structures as the board.

9. The board according to claim 8, wherein the board group is formed by stacking the other boards and the board.

10. The board according to claim 9, wherein the board group is configured in a two-unit chassis, and a quantity of layers of the board group is four.

11. A server, wherein the server is configured with a board, and the board is configured with a first processor and a second processor;
the first processor is provided with a corresponding first internal connector configuration area, and the first internal connector configuration area is arranged close to one side of the first processor;
the second processor is provided with a corresponding second internal connector configuration area, and the second internal connector configuration area is arranged close to one side of the second processor;
the first processor is configured with a corresponding first internal connector, and the second processor is configured with a corresponding second internal connector; and
the first internal connector is arranged in the second internal connector configuration area, and the second internal connector is arranged in the first internal connector configuration area; the first processor and the first internal connector are electrically connected through a first circuit, and the second processor and the second internal connector are electrically connected through a second circuit.

12. The server according to claim 11, wherein the first processor is provided with a corresponding third internal connector configuration area, and the third internal connector configuration area is arranged at a central area of the board close to one side of the first processor;
the second processor is provided with a corresponding fourth internal connector configuration area, and the fourth internal connector configuration area is arranged at the central area close to one side of the second processor;
the first processor is configured with a corresponding third internal connector, and the second processor is configured with a corresponding fourth internal connector; and
the third internal connector is arranged in the third internal connector configuration area, and the fourth internal connector is arranged in the fourth internal connector configuration area; the first processor and the third internal connector are electrically connected through a third circuit, the second processor and the fourth internal connector are electrically connected through a fourth circuit, and the third circuit does not intersect with the fourth circuit.

13. The server according to claim 12, wherein the third circuit and the first circuit do not intersect with the second circuit.

14. The server according to claim 12, wherein the fourth circuit and the first circuit do not intersect with the second circuit.

15. The server according to claim 11, wherein the first processor is provided with a corresponding first external connector configuration area, and the first external connector configuration area is arranged at an upper edge position of the board close to one side of the first processor.

16. The server according to claim 12, wherein the second processor is provided with a corresponding second external connector configuration area, and the second external connector configuration area is arranged at an upper edge position of the board close to one side of the second processor.

17. The server according to claim 16, wherein the first processor is configured with a corresponding first external connector, and the second processor is configured with a corresponding second external connector;
the first external connector are arranged in the first external connector configuration area, and the second external connector is arranged in the second external connector configuration area; the first processor and the first external connector are electrically connected through a fifth circuit, the second processor and the second external connector are electrically connected through a sixth circuit, and the fifth circuit does not intersect with the sixth circuit.

18. The server according to claim 12, wherein the board is connected to other boards through the first internal connector, the second internal connector, the third internal connector and the fourth internal connector to form a board group;
the other boards have same structures as the board.

19. The server according to claim 18, wherein the board group is formed by stacking the other boards and the board.

20. The server according to claim 19, wherein the board group is configured in a two-unit chassis, and a quantity of layers of the board group is four.
